(19) United States
(12) Patent Application Publication
(10) Pub. No.: US 2026/0052718 A1
(43) Pub. Date: Feb. 19, 2026

(54) SEMICONDUCTOR DEVICE

(71) Applicant: Vanguard International Semiconductor Corporation, Hsinchu (TW)

(72) Inventors: Yi-Wei LIEN, Hsinchu (TW); Hao-Ching HSU, Xihu Township (TW); Wei-Chih CHENG, Tainan City (TW)

(73) Assignee: Vanguard International Semiconductor Corporation, Hsinchu (TW)

(21) Appl. No.: 18/804,596

(22) Filed: Aug. 14, 2024

(51) Int. Cl. H01L 29/778; H01L 29/20; H01L 29/40; H01L 29/417

(52) U.S. Cl. CPC H10D 30/475; H10D 62/8503; H10D 64/112; H10D 64/257

(57) ABSTRACT

A semiconductor device is provided. The semiconductor device includes a substrate, a gate structure, first and second interlayer dielectric layers, a drain structure and a first field plate. The first interlayer dielectric layer partially covers the substrate and the gate structure disposed on the substrate. The drain structure is located on a first side of the gate structure. A drain electrode layer of the drain structure extends from the substrate not covered by the first interlayer dielectric layer to cover a first top surface of the first interlayer dielectric layer. The second interlayer dielectric layer is disposed on the first interlayer dielectric layer and covers the drain electrode layer. The first field plate is disposed on the second interlayer dielectric layer and partially overlaps the drain electrode layer on the first top surface of the first interlayer dielectric layer. The first field plate is electrically floating.

### BACKGROUND OF THE INVENTION

### Field of the Invention

The present disclosure relates to a semiconductor device, and, in particular, to a high electron mobility transistor device.

### Description of the Related Art

High electron mobility transistors, also called heterostructure FETs (HFETs) or modulation-doped FETs (MODFETs), are field effect transistors composed of semiconductor materials with different energy gaps. A two-dimensional electron gas (2DEG) layer will be generated at the interface between different semiconductor materials that are adjacent. Due to the high electron mobility of two-dimensional electron gas, high electron mobility transistor devices have the advantages of high breakdown voltage, high electron mobility, low on-resistance and low input capacitance, and are therefore suitable for use in high-power components.

However, although existing high electron mobility transistor devices are generally suitable for their intended purposes, they have not been entirely satisfactory in all respects. Therefore, there is a need to further improve high electron mobility transistor devices and methods for forming the same to improve performance and reliability.

### BRIEF SUMMARY OF THE INVENTION

An embodiment of the disclosure provides a semiconductor device. The semiconductor device includes a substrate, a gate structure, a first interlayer dielectric layer, a drain structure, a second interlayer dielectric layer and a first field plate. The gate structure is disposed on the substrate. The first interlayer dielectric layer is disposed on the substrate and partially covers the substrate and the gate structure. The drain structure is disposed on the substrate and located on a first side of the gate structure. The drain structure includes a drain electrode layer. The drain electrode layer is disposed on the substrate and extends from the substrate that is not covered by the first interlayer dielectric layer to cover a portion of the first top surface of the first interlayer dielectric layer. The second interlayer dielectric layer is disposed on the first interlayer dielectric layer and covers the drain electrode layer. The first field plate is disposed on the second interlayer dielectric layer and partially overlaps the drain electrode layer on the first top surface of the first interlayer dielectric layer. The first field plate is electrically floating.

### BRIEF DESCRIPTION OF THE DRAWINGS

The present invention can be more fully understood by reading the subsequent detailed description and examples with references made to the accompanying drawings, wherein:

FIG. 1 is a schematic cross-sectional view of a semiconductor device in accordance with some embodiments of the disclosure; and

FIG. 2 is a schematic cross-sectional view of a semiconductor device in accordance with some embodiments of the disclosure.

### DETAILED DESCRIPTION OF THE INVENTION

The embodiments of the present disclosure are described fully hereinafter with reference to the accompanying drawings. It should be noted, however, that the present disclosure is not limited to the following exemplary embodiments, and may be implemented in various forms. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the disclosure.

The following disclosure provides various embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

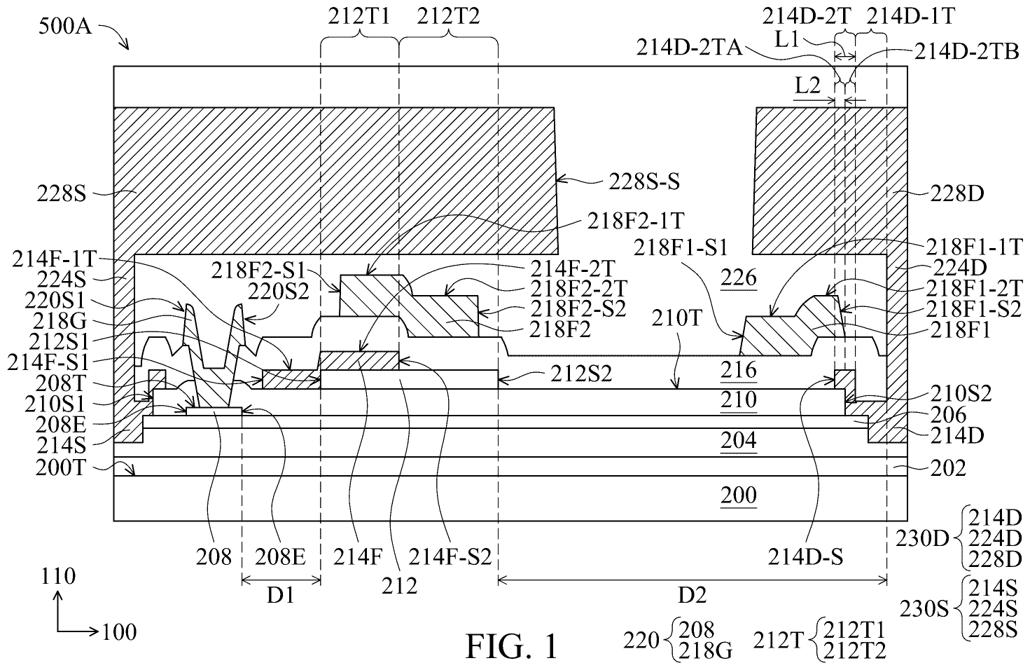

FIG. 1 is a schematic cross-sectional view of a semiconductor device 500A in accordance with some embodiments of the disclosure. In some embodiments, the semiconductor device 500A includes a high electron mobility transistor (HEMT), such as a gallium nitride-based enhancement-mode high electron mobility transistor (E-mode GaN HEMT). As shown in FIG. 1, the semiconductor device 500A includes a substrate 200, a gate structure 220, an interlayer dielectric layer 210, an interlayer dielectric layer 216, a source structure 230S, a drain structure 230D and a field plate 218F1.

In some embodiments, the substrate 200 includes an elementary semiconductor including silicon (Si) or germanium (Ge); a compound semiconductor including gallium arsenide (GaAs), gallium phosphide (GaP), indium phosphide (InP), indium arsenide (InAs) and/or indium antimonide (InSb); an alloy semiconductor including SiGe, GaAsP, AlInAs, AlGaAs, GaInAs, GaInP, and/or GaInAsP, or a combination thereof.

In some embodiments, the substrate 200 may be a semiconductor on insulator substrate, such as a silicon on insulator (SOI) substrate or a silicon germanium on insulator (SGOI) substrate. In other embodiments, the substrate 200 may be a ceramic substrate, such as an aluminum nitride (AlN) substrate, a silicon carbide (SiC) substrate, an aluminum oxide (Al2O3) substrate (or called a sapphire (sapphire) substrate), a glass substrate, or other similar substrates. In some embodiments, the substrate 200 may include a ceramic substrate and a pair of blocking layers respectively disposed on upper and lower surfaces of the ceramic substrate. The ceramic substrate may include a ceramic material, and the ceramic material may include a metal-inorganic material. For example, the ceramic substrate may include silicon carbide (SiC), aluminum nitride (AlN), sapphire substrate, or other suitable materials. The sapphire substrate may be aluminum oxide. In some embodiments, the blocking layers located on the top and bottom surfaces of the ceramic substrate may include a single layer or multiple layers of insulating material and/or other suitable material layers, such as semiconductor layers. The insulating material layer may be oxide, nitride, oxynitride, or other suitable insulating materials. The semiconductor layer may be polysilicon. The blocking layer may be capable of preventing the diffusion of the ceramic substrate. The blocking layer may also prevent the ceramic substrate from interacting with other film layers or processing tools. In some embodiments, the blocking layer may also encapsulate the ceramic substrate. At this time, the barrier layer may not only cover the top and bottom surfaces of the ceramic substrate, but also cover both side surfaces of the ceramic substrate.

In some embodiment, the semiconductor device 500A further includes a buffer layer 202. As shown in FIG. 1, the buffer layer 202 is located on the top surface 200T of the substrate 200. Since the crystal lattice and the coefficient of thermal expansion of the substrate 200 may be different from those of the features (such as a channel layer 204) above the substrate 200, strains may occur at or near the interface between the substrate 200 and the features above the substrate 200, resulting in defects such as cracks or warpage. Therefore, the buffer layer 202 on the substrate 200 can relief the strains in the features formed above the buffer layer 202 (e.g., the channel layer 204), preventing defects from forming in the above features. In some embodiments, the material of the buffer layer 202 may include III-V compound semiconductor materials, such as III-nitride. For example, the material of the buffer layer 202 may include: aluminum nitride (AlN), gallium nitride (GaN), aluminum gallium nitride (AlₓGa₁₋ₓN, where 0<x<1), aluminum nitride Indium (AlInN), a combination of thereof, or other similar materials. In some embodiments, the buffer layer 202 may be formed by an epitaxial growth process, such as metal organic chemical vapor deposition (MOCVD), hydride vapor phase epitaxy (HVPE), molecular beam epitaxy (MBE), other suitable methods, or a combination of thereof. In some embodiments, the buffer layer 202 may be a multi-layer structure (not shown). For example, the buffer layer 202 may include a superlattice buffer layer and/or a gradient buffer layer. The superlattice buffer layer may be disposed on the substrate 200, and the gradient buffer layer is disposed on the superlattice buffer layer. The buffer layer 202 may effectively prevent dislocations in the substrate 200 from entering the features above the substrate 200. The buffer layer 202 may further improve the crystallization quality of other overlying films and/or layers.

In some embodiments, the semiconductor device 500A may optionally include a seed layer (not shown) between the substrate 200 and the buffer layer 202. The seed layer can relieve the lattice difference between the substrate 200 and the films and/or layers growing thereon, so as to improve the crystallization quality. In some embodiments, the material of the seed layer may include aluminum nitride (AlN), aluminum gallium nitride (AlGaN), other suitable materials, or a combination of thereof. In some embodiments, the seed layer of a single-layer or multi-layer structure may be formed by, for example, chemical vapor deposition (CVD), atomic layer deposition (ALD), physical vapor deposition (PVD), other suitable processes, or a combination of thereof.

In some embodiments, the semiconductor device 500A further includes the channel layer 204. As shown in FIG. 1, the channel layer 204 is located on the buffer layer 202. In some embodiments, the material of the channel layer 204 includes a binary compound semiconductor of group III-V, such as group-III nitride. For example, the material of the channel layer 204 includes gallium nitride (GaN). In some embodiments, the channel layer 204 may be doped with n-type dopants or p-type dopants. In some embodiments, the channel layer 204 may be formed by an epitaxial growth process, such as metal organic chemical vapor deposition (MOCVD), hydride vapor phase epitaxy (HVPE), molecular beam epitaxy (MBE), liquid phase epitaxy (LPE), other suitable processes, or a combination of thereof.

In some embodiments, the semiconductor device 500A further includes a barrier layer 206. As shown in FIG. 1, the barrier layer 206 is located on the channel layer 204. The material of the barrier layer 206 may include a ternary compound semiconductor of group III-V, such as group-III nitride. For example, the material of the barrier layer 206 may be aluminum gallium nitride (Al_{y}Ga_{1-y}N, where 0<y<1), aluminum indium nitride (AlInN), or a combination thereof. In other embodiments, the barrier layer 206 may also include gallium nitride (GaN), aluminum nitride (AlN), gallium arsenide (GaAs), gallium indium phosphide (GaInP), aluminum gallium arsenide (AlGaAs), indium phosphide (InP), indium aluminum arsenide (InAlAs), indium gallium arsenide (InGaAs), other suitable III-V materials, or a combination of thereof. In some embodiments, the barrier layer 206 may be doped with n-type dopants or p-type dopants. In some embodiments, the barrier layer 206 may be formed by an epitaxial growth process, such as metal organic chemical vapor deposition (MOCVD), hydride vapor phase epitaxy (HVPE), molecular beam epitaxy (MBE), liquid phase epitaxy (LPE), other suitable processes, or a combination of thereof.

According to some embodiments of the disclosure, the channel layer 204 and the barrier layer 206 include different materials, and the interface between the channel layer 204 and the barrier layer 206 is a heterojunction structure. The lattice mismatch between the channel layer 204 and barrier layer 206 may result in stress that leads to piezoelectric polarization effect. In addition, the ionicity of the bonding between the group-III metals (such as aluminum (Al), gallium (Ga), or indium (In)) and nitrogen bonding is relatively strong, thereby resulting in spontaneous polarization. Due to the difference in energy gap between the heterogeneous materials of the channel layer 204 and the barrier layer 206 and the aforementioned piezoelectric polarization and spontaneous polarization effects, two-dimensional electron gas (2DEG) (not shown) is formed at the heterogeneous interface between the channel layer 204 and the barrier layer 206. In some embodiments, the two-dimensional electron gas is used as the conductive carriers of the semiconductor device 500A.

The gate structure 220 is disposed on the barrier layer 206 and covers a portion of the barrier layer 206. In some embodiments, the gate structure 220 includes a gate layer 208 and a gate electrode layer 218G.

The gate layer 208 is located on a portion of the barrier layer 206 and is in contact with the barrier layer 206. As shown in FIG. 1, the gate layer 208 may have a rectangular cross section as shown in FIG. 1. In addition, the cross section of the gate layer 208 may also be in other shapes, such as a trapezoidal cross section. In some embodiments, the material of the gate layer 208 may include n-type or p-type doped III-V semiconductors, such as: gallium nitride (GaN), aluminum gallium nitride (AlGaN), aluminum nitride (AlN), arsenic Gallium (GaAs), aluminum gallium arsenide (AlGaAs), indium phosphide (InP), aluminum indium arsenide (InAlAs), indium gallium arsenide (InGaAs), or other III-V semiconductors. In other embodiments, the gate layer 208 includes p-type doped II-VI semiconductors, such as cadmium sulfide (CdS), cadmium telluride (CdTe), zinc sulfide (ZnS), or other II-VI semiconductors. In some embodiments, the gate layer 208 is formed by metal organic chemical vapor deposition (MOCVD), hydride vapor phase epitaxy (HVPE), molecular beam epitaxy (MBE), a combination of thereof, or other suitable methods and subsequent patterning process. In this embodiment, the gate layer 208 may be doped. For example, the dopants may include magnesium (Mg), zinc (Zn), calcium (Ca), beryllium (Be), strontium (Sr), barium (Ba), radium (Ra), carbon (C), silver (Ag), gold (Au), lithium (Li) or sodium (Na), so that the conductivity type of the gate layer 208 is p-type.

The gate electrode layer 218G is located on gate layer 208. The gate electrode layer 218G is in contact with and partially covers the top surface 208T of gate layer 208. In some embodiments, the material of the gate electrode layer 218G may include a single-layer or multi-layer structure formed by metal, metal nitride, metal oxide, metal alloy, other suitable conductive materials, or a combination of thereof, or a combination of thereof. The metals may include, for example, gold (Au), nickel (Ni), platinum (Pt), palladium (Pd), iridium (Ir), titanium (Ti), chromium (Cr), tungsten (W), aluminum (Al), copper (Cu), similar materials, an alloy thereof, or a combination thereof. The metal alloy may include titanium tungsten (TiW). The metal nitrides may include molybdenum nitride (MoN), tungsten nitride (WN), titanium nitride (TiN), tantalum nitride (TaN), tantalum silicon nitride (TaSiN), tantalum carbide nitride (TaCN), nitrogen aluminum titanium (TiAlN), or other similar materials. In other embodiments, the conductive material of the gate electrode layer 218G may include nickel silicide (NiSi), cobalt silicide (CoSi), tantalum carbide (TaC), titanium aluminide (TiAl), or other similar materials. In this embodiment, the gate electrode layer 218G is titanium nitride (TiN).

In some embodiments, the gate electrode layer 218G may be formed by a deposition process followed by a patterning process. For example, the deposition process may include chemical vapor deposition (CVD), atomic layer deposition (ALD), or physical vapor deposition (PVD) such as sputtering or evaporation.

As shown in FIG. 1, the semiconductor device 500A further includes an interlayer dielectric layer 210 disposed on the barrier layer 206. Furthermore, the interlayer dielectric layer 210 partially covers the gate structure 220. As shown in FIG. 1, the interlayer dielectric layer 210 is in contact with opposite side surfaces (not shown) of the gate layer 208, a portion of the top surface 208T of the gate layer 208, a portion of side surfaces of the gate electrode layer 218G, and the barrier layer 206 that is not covered by the gate structure 220.

In some embodiments, the interlayer dielectric layer 210 may be a single-layer structure or a multi-layer structure. In this embodiment, the interlayer dielectric layer 210 may be a single-layer structure or a multi-layer structure formed of the same material.

In some embodiments, the interlayer dielectric layer 210 may include dielectric materials such as silicon oxide, silicon nitride, silicon oxynitride, tetraethoxysilane (TEOS) oxide, phosphosilicate glass (PSG), borosilicate glass (BSG), borophosphosilicate glass (BPSG), undoped silicate glass (USG), fluorinated silicate glass (FSG), organosilicate glasses (OSG), low-k dielectric materials, and/or other suitable dielectric materials, or a combination of thereof. The low-k dielectric materials may include (but not limited to) fluorinated silica glass (FSG), hydrogen silsesquioxane (HSQ), carbon-doped silicon oxide, amorphous fluorinated carbon, parylene, bis-benzocyclobutene (BCB), polyimide, or a combination thereof. In some embodiments, the interlayer dielectric layer 210 may be formed by a deposition process. For example, the deposition process may include spin-on coating, chemical vapor deposition (CVD), atomic layer deposition (ALD), low-pressure chemical vapor deposition (LPCVD), high-density plasma chemical vapor deposition (HDPCVD), other suitable processes, or a combination of thereof.

As shown in FIG. 1, the source structure 230S and the drain structure 230D are disposed on the substrate 200. The source structure 230S and the drain structure 230D are respectively located on a first side surface 220S1 and a second side surface 220S2 of the gate structure 220 in a direction 100 that is substantially parallel to the top surface 200T of the substrate 200 (which can also be regarded as a lateral direction). Furthermore, the source structure 230S and the drain structure 230D are respectively adjacent to the opposite side surfaces 210S1 and 210S2 of the interlayer dielectric layer 210 in the direction 100. As shown in FIG. 1, the source structure 230S and the drain structure 230D located on both sides of the gate layer 208 are separated from the gate layer 208 by the interlayer dielectric layer 210 in the direction 100. In addition, the interlayer dielectric layer 210 extends between the source structure 230S and the drain structure 230D in the direction 100. The source feature 230S and the drain feature 230D respectively extend from above the interlayer dielectric layer 210 into a portion of the channel layer 204 along the direction 110 that is substantially perpendicular to the top surface 200T of the substrate 200 (which can also be regarded as a vertical direction) and are in contact with the channel layer 204.

In some embodiments, the drain structure 230D may be a composite structure (a multi-layer structure), which may include a drain electrode layer 214D, a drain contact feature 224D, and a drain metal layer 228D in sequence from bottom to top. The drain electrode layer 214D is disposed on the substrate 200 and the barrier layer 206. The drain electrode layer 214D may extend toward the gate structure 220 in the direction 100. In addition, the drain electrode layer 214D may extend from the substrate 200 and the barrier layer 206 that are not covered by the interlayer dielectric layer 210 to cover a portion of the top surface 210T of the interlayer dielectric layer 210 in the direction 100. The drain contact feature 224D is located on the drain electrode layer 214D and extends in the direction 110. The drain metal layer 228D is located on the drain contact feature 224D and extends in the direction 100. In some embodiments, the drain metal layer 228D completely covers drain electrode layer 214D.

In some embodiments, the drain electrode layer 214D is conformally formed on the interlayer dielectric layer 210 and the barrier layer 206. In the cross-sectional view shown in FIG. 1, the drain electrode layer 214D has a stepped shape. In this embodiment, the step number of the stepped drain electrode layer 214D is 2. Therefore, the drain electrode layer 214D may have two upper surfaces 214D-1T, 214D-2T. As shown in FIG. 1, the upper surface 214D-1T of the drain electrode layer 214D is located directly above the top surface 200T of the substrate 200 that is not covered by the interlayer dielectric layer 210. The upper surface 214D-2T of the drain electrode layer 214D is located directly above the top surface 210T of the interlayer dielectric layer 210. In some embodiments, the upper surfaces 214D-1T, 214D-2T are not coplanar with each other. For example, in the direction 110, the upper surface 214D-1T is located below the upper surface 214D-2T (that is, the upper surface 214D-1T is closer to the top surface 200T of the substrate 200 than the upper surface 214D-2T).

In some embodiments, the source structure 230S may be a composite structure (a multi-layer structure), which may include a source electrode layer 214S, a source contact feature 224S, and a source metal layer 228S in sequence from bottom to top. The source electrode layer 214S is disposed on the substrate 200 and the barrier layer 206. The source electrode layer 214S may extend toward the gate structure 220 in the direction 100. In addition, the source electrode layer 214S may extend from the substrate 200 and the barrier layer 206 that are not covered by the interlayer dielectric layer 210 to cover another portion of the top surface 210T of the interlayer dielectric layer 210 in the direction 100. Therefore, in the cross-sectional view shown in FIG. 1, the source electrode layer 214S has a stepped shape. The drain electrode layer 214D and the source electrode layer 214S may cover different portions of the top surface 210T of the interlayer dielectric layer 210. The source contact feature 224S is located on the source electrode layer 214S and extends in the direction 110. The source metal layer 228S is located on the source contact feature 224S and extends in the direction 100. In some embodiments, the source metal layer 228S completely covers the source electrode layer 214S.

In some embodiments, the source electrode layer 214S is conformally formed on the interlayer dielectric layer 210 and the barrier layer 206. In the cross-sectional view shown in FIG. 1, the source electrode layer 214S has a stepped shape. For example, the step number of the stepped source electrode layer 214S is 2. In addition, the source electrode layer 214S may have two upper surfaces.

In some embodiments, the drain electrode layer 214D and the source electrode layer 214S are formed simultaneously. The drain contact feature 224D and the source contact feature 224S are formed simultaneously. In addition, the drain metal layer 228D and the source metal layer 228S are formed simultaneously.

The interlayer dielectric layer 216 is disposed on the interlayer dielectric layer 210 and extends from the source structure 230S to the drain structure 230D. As shown in FIG. 1, the interlayer dielectric layer 216 may cover the drain electrode layer 214D and the source electrode layer 214S. In addition, the interlayer dielectric layer 216 is adjacent to the drain contact feature 224D and the source contact feature 224S. In other words, the drain contact feature 224D and the source contact feature 224S may pass through the interlayer dielectric layer 216 in the direction 110.

In some embodiments, the interlayer dielectric layers 210 and 216 may include the same or similar materials and processes. For example, the interlayer dielectric layer 216 and the interlayer dielectric layer 210 are both silicon dioxide and have the same dielectric constant (k=3.9).

The semiconductor device 500A may include a plurality of the field plates, which may make the electric field distribution on the surface of the semiconductor device 500A relatively uniform. The field plate may include a field plate 218F1 disposed on the drain side of the semiconductor device 500A (close to the drain structure 230D) and overlapping the drain electrode layer 214D. As shown in FIG. 1, the field plate 218F1 is disposed on the interlayer dielectric layer 216. The field plate 218F1 may partially overlap the drain electrode layer 214D on the top surface 210T of the interlayer dielectric layer 210. In addition, the field plate 218F1 may extend toward the drain contact feature 224D in the direction 100. More specifically, in the direction 110, the field plate 218F1 may overlap a portion of the drain electrode layer 214D on the top surface 210T of the interlayer dielectric layer 210. Furthermore, the field plate 218F1 does not overlap the portion of the drain electrode layer 214D located on the barrier layer 206 that is not covered by the interlayer dielectric layer 210. Therefore, the field plate 218F1 is closer to the gate structure 220 than the drain electrode layer 214D. As shown in FIG. 1, the field plate 218F1 may extend from the top surface 210T of the interlayer dielectric layer 210 that is not covered by the drain electrode layer 214D to cover a first portion 214D-2TA of the top surface 214D-2T of the drain electrode layer 214D in the direction 100, so that a second portion 214D-2TB of the upper surface 214D-2T is exposed from the field plate 218F1. The first portion 214D-2TA and the second portion 214D-2TB of the upper surface 214D-2T of the drain electrode layer 214D are adjacent to each other and are different portions of the upper surface 214D-2T of the drain electrode layer 214D.

In the direction 100, the upper surface 214D-2T of the drain electrode layer 214D has a length L1, and the first portion 214D-2TA of the upper surface 214D-2T has a length L2. In some embodiments, the ratio of the length L1 to the length L2 is greater than or equal to 2 (i.e., L1/L2≥2). If the ratio of the length L1 to the length L2 is less than 2, the overlapping portion of the field plate 218F1 and the drain electrode layer 214D may be too large and affect the uniformity of the surface electric field.

In some embodiments, the field plate 218F1 is conformally formed on the interlayer dielectric layer 210 and the drain electrode layer 214D. In the cross-sectional view shown in FIG. 1, the drain electrode layer 214D has a stepped shape. In this embodiment, the step number of the stepped drain electrode layer 214D is 2. Therefore, the field plate 218F1 may have two upper surfaces 218F1-1T, 218F1-2T and opposite side surfaces 218F1-S1, 218F1-S2 connected to the upper surfaces 218F1-1T, 218F1-2T respectively. As shown in FIG. 1, the upper surface 218F1-1T of the field plate 218F1 is located directly above the top surface 210T of the interlayer dielectric layer 210 that is not covered by the drain electrode layer 214D. The upper surface 218F1-2T of the field plate 218F1 is located directly above the first portion 214D-2TA of the upper surface 214D-2T of the drain electrode layer 214D. In some embodiments, the upper surfaces 218F1-1T, 218F1-2T of the field plate 218F1 is not coplanar with each other. For example, in the direction 110, the upper surface 218F1-1T is located below the upper surface 218F1-2T (that is, the upper surface 218F1-1T is closer to the top surface 200T of the substrate 200 than the upper surface 218F1-2T).

As shown in FIG. 1, the side surface 218F1-S1 of the field plate 218F1 close to the gate structure 220 is not located directly above the drain electrode layer 214D. The side surface 218F1-S2 of the field plate 218F1 close to the drain structure 230D is located directly above the drain electrode layer 214D. Therefore, the side surface 218F1-S1 of the field plate 218F1 close to the gate structure 220 is closer to the gate structure 220 than the side surface 214D-S of the drain electrode layer 214D close to the gate structure 220.

In some embodiments, the field plate 218F1 may include polycrystalline silicon, a metal (such as tungsten, titanium, aluminum, copper, iron, molybdenum, nickel, platinum, the like, or a combination thereof), a metal alloy (such as nickel iron alloy (NiFe), beryllium copper alloy (BeCu), metal nitrides (such as tungsten nitride, molybdenum nitride, titanium nitride, tantalum nitride, the like, or a combination thereof), metal silicides (such as tungsten silicide, titanium silicide, cobalt silicide, nickel silicide, platinum silicide, erbium silicide, the like, or a combination thereof), metal oxides (ruthenium oxide, indium tin oxide, the like, or a combination thereof), other suitable conductive materials, or a combination thereof. In some embodiments, the field plate 218F1 may be formed by a deposition process and a subsequent patterning process. The deposition process may include chemical vapor deposition (CVD), atomic layer deposition (ALD), physical vapor deposition (PVD), molecular beam deposition (MBE), plasma enhanced chemical vapor deposition (PECVD), other suitable processes, or a combination thereof.

As shown in FIG. 1, the semiconductor device 500A also includes a dielectric pattern 212. The dielectric pattern 212 is disposed on a portion of the interlayer dielectric layer 210 between the gate structure 220 and the drain structure 230D. Furthermore, the dielectric pattern 212 covers a portion of the top surface 210T of the interlayer dielectric layer 210. The dielectric pattern 212 has a top surface 212T and opposite side surfaces 212S1 and 212S2 connected to the top surface 212T. The side surfaces 212S1 and 212S2 of the dielectric pattern 212 are both located on the top surface 210T of the interlayer dielectric layer 210. In a direction 110 that is substantially perpendicular to the top surface 200T of the substrate 200 (which can also be regarded as the vertical direction), the dielectric pattern 212 may partially overlap the interlayer dielectric layer 210. As shown in FIG. 1, in the direction 100 that is substantially parallel to the top surface 200T of the substrate 200 (which can also be regarded as the lateral direction), the side surface 212S1 of the dielectric pattern 212 is separated from the gate layer 208 of the gate structure 220 by a first distance D1. Furthermore, the side surface 212S2 of the dielectric pattern 212 is separated from the drain contact feature 224D of the drain structure 230D by a second distance D2. In some embodiments, the first distance D1 is less than the second distance D2. In other words, in the direction 100, the gate structure 220 is closer to the dielectric pattern 212 than the drain contact feature 224D of the drain structure 230D.

In some embodiments, the dielectric pattern 212 may include dielectric materials, such as silicon oxide (SiO₂), silicon nitride (SiNₓ), silicon oxynitride (SiON), tetraethoxysilane (TEOS) oxide, phosphosilicate glass (PSG), borosilicate glass (BSG), borophosphosilicate glass (BPSG), undoped silicate glass (USG), fluorinated silicate glass (FSG), organosilicate glasses (OSG), and/or other suitable dielectric materials, or a combination thereof. In some embodiments, the dielectric pattern 212 may include a low-dielectric constant (low-k) dielectric material, a high-k dielectric material (the dielectric constant (k) of the high-k dielectric material is higher than the dielectric constant of silicon oxide (SiO₂) (k=3.9)), and/or other suitable dielectric materials, or a combination thereof. The low-k dielectric materials may include (but not limited to) fluorinated silica glass (FSG), hydrogen silsesquioxane (HSQ), carbon-doped silicon oxide, amorphous fluorinated carbon, parylene, bis-benzocyclobutene (BCB), polyimide, or a combination thereof. The high-k dielectric materials may include (but are not limited to) silicon nitride, hafnium oxide, hafnium silicon oxide, hafnium silicon oxynitride, hafnium tantalum oxide, hafnium titanium oxide, hafnium zirconium oxide, zirconium oxide, aluminum oxide, hafnium dioxide-alumina alloy, and/or a combination thereof or the like. In some embodiments, the dielectric pattern 212 may be a single-layer structure or a multi-layer structure formed of the above-mentioned dielectric materials.

In some embodiments, the interlayer dielectric layers 210, 216 and the dielectric pattern 212 include different materials. In some embodiments, the dielectric constant of the interlayer dielectric layers 210, 216 is different from the dielectric constant of the dielectric pattern 212. The dielectric constant of the interlayer dielectric layers 210, 216 may be less than the dielectric constant of the dielectric pattern 212. For example, the interlayer dielectric layers 210 and 216 are silicon dioxide (k=3.9), and the dielectric pattern 212 is silicon nitride (k=7.5).

In some embodiments, the dielectric pattern 212 may be formed by a deposition process and a subsequent patterning process. For example, the deposition process may include spin-on coating, chemical vapor deposition (CVD), atomic layer deposition (ALD), low pressure chemical vapor deposition (LPCVD), high density plasma chemical vapor deposition (HDPCVD), other suitable processes, or a combination thereof.

The field plate of the semiconductor device 500A further includes a field plate 214F and a field plate 218F2 that are disposed between the gate structure 220 and the drain structure 230D of the semiconductor device 500A and overlap the dielectric pattern 212.

The field plate 214F is disposed on the substrate 200. Furthermore, the field plate 214F covers the interlayer dielectric layer 210 between the gate structure 220 and the dielectric pattern 212 and the dielectric pattern 212. As shown in FIG. 1, the field plate 214F extends from the top surface 210T of the interlayer dielectric layer 210 to cover and contact the whole side surfaces 212S1 and a first portion 212T1 of the top surface 212T of the dielectric pattern 212 in the direction 100. In addition, a second portion 212T2 of the top surface 212T is exposed from the field plate 214F. In other words, the field plate 214F does not extend to cover the side surface 212S2 of the dielectric pattern 212 close to the drain structure 230D, which can reduce the risk of a short circuit between the field plate 214F and the drain structure 230D. Furthermore, the first portion 212T1 and the second portion 212T2 of the top surface 212T of the dielectric pattern 212 are adjacent to each other and are different portions of the top surface 212T of the dielectric pattern 212. For example, the first portion 212T1 of the top surface 212T of the dielectric pattern 212 is closer to the gate structure 220. In addition, the second portion 212T2 of the top surface 212T of the dielectric pattern 212 is closer to the drain structure 230D.

In some embodiments, the field plate 214F is conformally formed on the interlayer dielectric layer 210 and the dielectric pattern 212. Therefore, the field plate 214F has a stepped shape in the cross-sectional view shown in FIG. 1. In this embodiment, the step number of the stepped field plate 214F is 2. Therefore, the field plate 214F has two upper surfaces 214F-1T and 214F-2T in the direction 110. In addition, the field plate 214F has opposite side surfaces 214F-S1 and 214F-S2 respectively connected to the upper surfaces 214F-1T and 214F-2T. The upper surface 214F-1T of the field plate 214F is located directly above the portion of the interlayer dielectric layer 210 between the gate structure 220 and the dielectric pattern 212. The upper surface 214F-2T of the field plate 214F is located directly above the first portion 212T1 of the top surface 212T of the dielectric pattern 212. In some embodiments, the upper surfaces 214F-IT, 214F-2T are not coplanar with each other. For example, in the direction 110, the upper surface 214F-1T is located below the upper surface 214F-2T (that is, the upper surface 214F-1T is closer to the top surface 200T of the substrate 200 than the upper surface 214F-2T).

As shown in FIG. 1, the side surface 214F-S1 of the field plate 214F close to the gate structure 220 is located directly above the portion of the interlayer dielectric layer 210 between the gate structure 220 and the dielectric pattern 212. The side surface 214F-S2 of the field plate 214F close to the drain structure 230D is located directly above dielectric pattern 212. In some embodiments, the side surface 214F-S2 of the field plate 214F and side surface 212S2 of the dielectric pattern 212 close to the drain structure 230D are not aligned with each other.

In some embodiments, the field plate 214F and the field plate 218F1 may include the same or similar materials and processes. In some embodiments, the field plate 214F may be formed simultaneously with the source electrode layer 214S of the source structure 230S and the drain electrode layer 214D of the drain structure 230D.

As shown in FIG. 1, the interlayer dielectric layer 216 completely covers the dielectric pattern 212 and the field plate 214F, so that the dielectric pattern 212 and the field plate 214F are sandwiched between the interlayer dielectric layers 210 and 216 in the direction 110. More specifically, the interlayer dielectric layer 216 covers and is in contact with the interlayer dielectric layer 210 exposed from the dielectric pattern 212 and the field plate 214F. The interlayer dielectric layer 216 covers and is in contact with the upper surfaces 214F-1T, 214F-2T and the side surfaces 214F-S1, 214F-S2 of the field plate 214F. Furthermore, the interlayer dielectric layer 216 covers and is in contact with the second portion 212T2 of the top surface 212T and the side surface 212S2 of the dielectric pattern 212. As shown in FIG. 1, the field plate 214F and the interlayer dielectric layer 216 are respectively in contact with the opposite side surface surfaces 212S1 and 212S2 of the dielectric pattern 212. The drain feature 230D and the gate electrode layer 218G located on opposite sides of the field plate 214F are separated from the field plate 214F by the interlayer dielectric layer 216 in the direction 100.

The field plate 218F2 is disposed above the field plate 214F and the dielectric pattern 212 and extends toward the drain structure 230D. The field plate 218F2 covers a portion of interlayer dielectric layer 216 directly above the top surface 212T of the dielectric pattern 212. In addition, the field plate 218F2 is separated from the field plate 214F by the interlayer dielectric layer 216. In some embodiments, the field plate 214F partially overlaps the field plate 218F2. More specifically, in the direction 110, the field plate 218F2 overlaps a portion of the field plate 214F on the first portion 212T1 of the top surface 212T of the dielectric pattern 212. Moreover, the field plate 218F2 does not overlap with a portion of the field plate 214F on the interlayer dielectric layer 210 between the gate structure 220 and the dielectric pattern 212. Therefore, the field plate 218F2 is closer to the drain structure 230D than the field plate 214F. Furthermore, in the direction 110, the field plate 214F and the field plate 218F2 both overlap with the source metal layer 228S of the source structure 230S. As shown in FIG. 1, the source metal layer 228S may completely cover the field plate 214F and the field plate 218F2.

In some embodiments, the field plate 218F2 is conformally formed on the interlayer dielectric layer 210, the dielectric pattern 212, and the field plate 214F. Therefore, the field plate 218F2 has a stepped shape in the cross-sectional view shown in FIG. 1. In this embodiment, the step number of the stepped field plate 218F2 is 2. Therefore, the field plate 218F2 has two upper surfaces 218F2-1T, 218F2-2T in the direction 110. In addition, the field plate 218F2 has opposite side surfaces 218F2-S1, 218F2-S2 connected to the upper surfaces 218F2-1T, 218F2-2T respectively. The upper surface 218F2-1T of the field plate 218F2 is located directly above the first portion 212T1 of the top surface 212T of the dielectric pattern 212 (or the upper surface 214F-2T of the field plate 214F). The upper surface 218F2-2T of the field plate 218F2 is located directly above the second portion 212T2 of the top surface 212T of the pattern 212. In some embodiments, the upper surfaces 218F2-1T, 218F2-2T are not coplanar with each other. For example, in the direction 110, the upper surface 218F2-1T is located above the upper surface 218F2-2T (that is, the upper surface 218F2-2T is closer to the top surface 200T of the substrate 200 than the upper surface 218F2-1T).

As shown in FIG. 1, the side surface 218F2-S1 of the field plate 218F2 close to the gate structure 220 is located directly above the first portion 212T1 of the top surface 212T of the dielectric pattern 212 (or the top surface 214F-2T of the field plate 214F). In addition, the side surface 218F2-S2 of the field plate 218F2 close to the drain structure 230D is located directly above the second portion 212T2 of the top surface 212T of the dielectric pattern 212. In some embodiments, the field plate 218F2 is located directly over dielectric pattern 212 and covers a portion of the dielectric pattern 212. Accordingly, the opposite side surfaces 218F2-S1, 218F2-S2 of the field plate 218F2 are not aligned with the corresponding side surfaces 212S1, 212S2 of the dielectric pattern 212. Moreover, in the direction 100, the side surface 218F2-S2 of the field plate 218F2 close to the drain structure 230D is closer to the drain structure 230D than the side surface 214F-S2 of the field plate 214F close to the drain structure 230D. In addition, the side surface 228S-S of the source metal layer 228S of the source structure 230S close to the drain structure 230D is closer to the drain structure 230D than the side surface 218F2-S2 of the field plate 218F2.

In some embodiments, the field plate 214F, the field plate 218F1, and field plate 218F2 may include the same or similar materials and processes. In some embodiments, the field plate 218F1, the field plate 218F2, and the gate electrode layer 218G may be formed simultaneously.

As shown in FIG. 1, the semiconductor device 500A further includes an interlayer dielectric layer 226. The interlayer dielectric layer 226 is disposed on the interlayer dielectric layer 216. The interlayer dielectric layer 226 entirely covers the source structure 230S, the drain structure 230D and extends from the source structure 230S to the drain structure 230D. Furthermore, the drain feature 230D is separated from the field plates 218F1 and 218F2 by the interlayer dielectric layer 226 in the direction 100. In some embodiments, the interlayer dielectric layers 210, 216, 226 may include the same or similar materials and processes. Therefore, in some embodiments, the interlayer dielectric layer 226 and the dielectric pattern 212 include different materials. The dielectric constant of the interlayer dielectric layer 226 is different from the dielectric constant of the dielectric pattern 212. The dielectric constant of the interlayer dielectric layer 226 may be smaller than the dielectric constant of the dielectric pattern 212. For example, the interlayer dielectric layer 226 is silicon dioxide (k=3.9), and the dielectric pattern 212 is silicon nitride (k=7.5). In some embodiments, the interlayer dielectric layer 226 may be a single-layer structure or a multi-layer structure.

In this embodiment, the field plate 218F1 of the semiconductor device 500A extends toward the drain structure 230D in the direction 100. In addition, the field plate 218F1 of the semiconductor device 500A may partially overlap the drain electrode layer 214D in the direction 110. In some embodiments, the field plate 218F1 is electrically floating, which can avoid large electric field peak induced at the edge of the drain electrode layer (for example, at the side surface 214D-S of the drain electrode layer 214D close to the gate structure 220), thereby reducing the drain-to-source on resistance (R_{DS-ON}) and increasing the breakdown voltage of the high electron mobility transistor device. In this embodiment, the drain electrode layer 214D is a 2-step stepped drain electrode layer which is conformally formed on the barrier layer 206 and the interlayer dielectric layer 210. In addition, the field plate 218F1 is a 2-step stepped field plate which is conformally formed on the interlayer dielectric layer 216 and the drain electrode layer 214D, and is fabricated by a single-layer field plate process. Therefore, the field plate 218F1 may have the electric field redistribution ability comparable to the multi-layer field plate structure while saving the fabrication cost of a single-layer field plate structure (such as the fabrication cost of the photomask). Therefore, the number of the field plates and the capacitance generated between the gate electrode and the drain region can be reduced. The figure of merit (FOM) of the semiconductor device 500A can be improved (for example, by reducing the product of the on-resistance (drain-to-source on resistance, R_{DS-ON}) and the output power capacitance (C_{OSS}) of the semiconductor device 500A).

Furthermore, in some embodiments, when the dielectric pattern 212 is formed of a high-k dielectric material, such as silicon nitride, and the interlayer dielectric layer 210 is formed of silicon dioxide, the dielectric pattern 212 can withstand high electric fields. Therefore, the electric field distribution on the surface of the semiconductor device 500A can be relatively uniform. For example, the electric field peak at the edge of the subsequently formed field plate (for example, the side surface 214F-S2 of the field plate 214F close to the drain structure 230D) can be reduced. In addition, since the interlayer dielectric layer 210 and the dielectric pattern 212 are formed of different dielectric materials, the interlayer dielectric layer 210 may serve as an etching stop layer for the dielectric pattern 212 during the patterning process (including lithography and etching processes) for forming the dielectric pattern 212. In addition, the thickness of the interlayer dielectric layer 210 is not affected by the etching process. Therefore, the figure of merit (FOM) of the semiconductor device 500A (for example, the pinch-off voltage of the semiconductor device 500A) can be further improved.

Furthermore, in some embodiments, the field plate 214F and the field plate 218F2 of the semiconductor device 500A extend toward the drain structure 230D in the direction 100 and are electrically connected to the source structure 230S. Therefore, the field plate 214F and the field plate 218F2 can also serve as the source field plates 214F and 218F2, which can effectively reduce the surface electric field (REduced SURface Field, or RESURF). Furthermore, the field plate 214F is a stepped source field plate conformally formed on the interlayer dielectric layer 210 and the dielectric pattern 212. The field plate 218F2 is a stepped source field plate conformally formed on the interlayer dielectric layer 210, the dielectric pattern 212 and the field plate 214F. Therefore, a multi-layer (e.g., two-layer) field plate structure can be fabricated by a single-layer field plate process. The field plate 214F and the field plate 218F2 in accordance with some embodiments of the disclosure may have the electric field redistribution ability comparable to the multi-layer field plate structure while saving the fabrication cost of a single-layer field plate structure (such as the fabrication cost of the photomask), which can avoid large electric field peak induced at the edge of the drain electrode layer (for example, at the side surface 214F-S2 of the field plate 214F close to the drain structure 230D or the side surface 218F2-S2 of the field plate 218F2 close to the drain structure 230D), thereby reducing the drain-to-source on resistance (R_{DS-ON}) and increasing the breakdown voltage of the high electron mobility transistor device. In addition, the field plate 214F and the field plate 218F2 are disposed on different interlayer dielectric layers 210 and 216. Therefore, the distance between each field plate and the barrier layer 206 can be adjusted to further increase the breakdown voltage of the high electron mobility transistor (HEMT) device. Since the arrangement of the field plate 214F and the field plate 218F2 can reduce the source-to-drain on-resistance (R_{DS-ON}), the figure of merit (FOM) of the semiconductor device 500A can be further improved (for example, by reducing the product of the on-resistance (drain-to-source on resistance, R_{DS-ON}) and the output power capacitance (C_{OSS}) of the semiconductor device 500A).

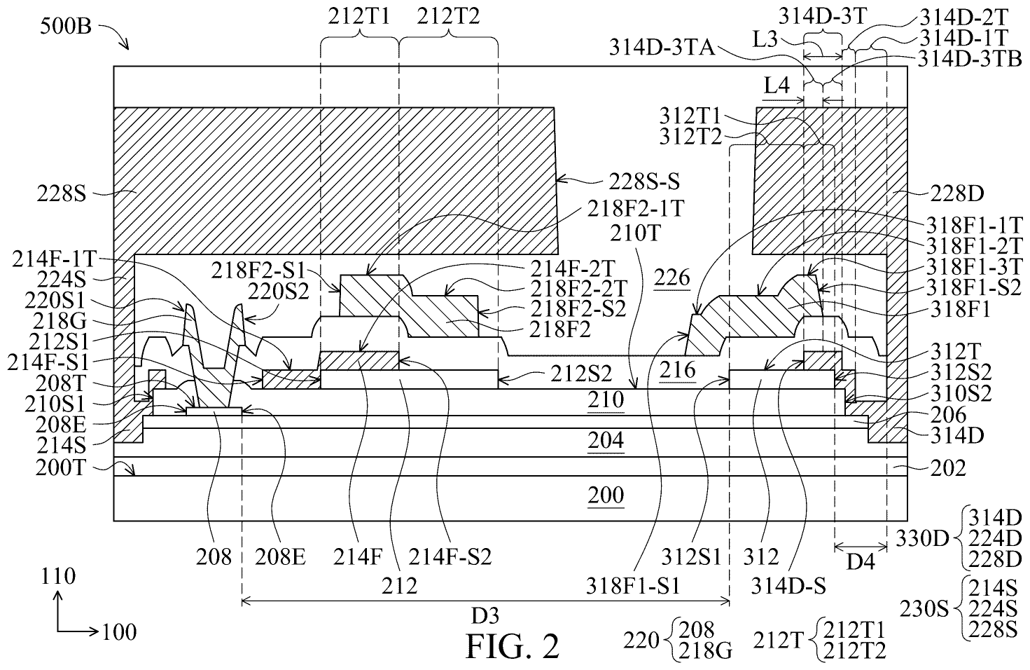

FIG. 2 is a schematic cross-sectional view of a semiconductor device 500B in accordance with some embodiments of the disclosure, in which the reference numbers the same or similar to those in FIG. 1 denote the same or similar elements. As shown in FIG. 2, the difference between the semiconductor device 500B and the semiconductor device 500A is at least that the semiconductor device 500B further includes a dielectric pattern 312. Additionally, the semiconductor device 500B replaces the drain electrode layer 214D with a drain electrode layer 314D, and replaces the field plate 218F1 with a field plate 318F1. Furthermore, the drain electrode layer 314D, the drain contact feature 224D, and the drain metal layer 228D collectively form a drain structure 330D. The dielectric pattern 312 is disposed on the drain side of the semiconductor device 500B (close to the drain structure 330D). In addition, the dielectric pattern 312 overlaps the drain electrode layer 314D and the field plate 218F1.

As shown in FIG. 2, the dielectric pattern 312 is disposed on a portion of the interlayer dielectric layer 210 between the gate structure 220 and the drain structure 330D. The dielectric pattern 312 covers a portion of the top surface 210T of the interlayer dielectric layer 210. As shown in FIG. 2, the interlayer dielectric layer 216 completely covers the dielectric pattern 312. Therefore, the dielectric pattern 312 is sandwiched between the interlayer dielectric layer 210 and the interlayer dielectric layer 216 in the direction 110 that is substantially perpendicular to the top surface 200T of the substrate 200 (which can also be regarded as the vertical direction). The dielectric pattern 312 has a top surface 312T and opposite side surfaces 312S1 and 312S2 connected to the top surface 312T. The side surfaces 312S1 and 312S2 of the dielectric pattern 312 are both located on the top surface 210T of the interlayer dielectric layer 210. In the direction 110 (which can also be regarded as the vertical direction), the dielectric pattern 312 may partially overlap the interlayer dielectric layer 210.

As shown in FIG. 2, in the direction 100 that is substantially parallel to the top surface 200T of the substrate 200 (which can also be regarded as the lateral direction), the side surface 312S1 of the dielectric pattern 312 is separated from the gate layer 208 of the gate structure 220 by a third distance D3. The side surface 312S2 of the dielectric pattern 312 is separated from the drain contact feature 224D of the drain structure 330D by a fourth distance D4. In some embodiments, the third distance D3 is greater than the fourth distance D4. In other words, in the direction 100, the drain contact feature 224D of the drain structure 330D is closer to the dielectric pattern 312 than the gate structure 220.

The dielectric pattern 212 and the dielectric pattern 312 cover different portions of the top surface 210T of the interlayer dielectric layer 210. Also, in the direction 100, the dielectric pattern 212 and dielectric pattern 312 are spaced apart from each other. In some embodiments, the third distance D3 is greater than the first distance D1, and the fourth distance D4 is less than the second distance D2. In other words, in the direction 100, the dielectric pattern 212 is closer to the gate structure 220 than the dielectric pattern 312. In addition, the dielectric pattern 312 is closer to drain contact feature 224D of the drain structure 330D than dielectric pattern 212.

As shown in FIG. 2, in this embodiment, the drain electrode layer 314D is conformally formed on the barrier layer 206, the interlayer dielectric layer 210 and the dielectric pattern 312. In the cross-sectional view shown in FIG. 1, the drain electrode layer 314D has a stepped shape. In this embodiment, the step number of the stepped drain electrode layer 314D is 3. Therefore, the drain electrode layer 314D has three upper surfaces 314D-1T, 314D-2T, 314D-3T. As shown in FIG. 2, the upper surface 314D-1T of the drain electrode layer 314D is located directly above the top surface 200T of the substrate 200 (or the barrier layer 206) that is not covered by the interlayer dielectric layer 210. The upper surface 314D-2T of the drain electrode layer 314D is located directly above the top surface 210T of the interlayer dielectric layer 210 that is not covered by the dielectric pattern 312 and close to the drain contact feature 224D. The upper surface 314D-3T of the drain electrode layer 314D is located directly above the third portion 312T1 of the top surface 312T of the dielectric pattern 312. Therefore, the fourth portion 312T2 of the top surface 312T of the dielectric pattern 312 is exposed from the drain electrode layer 314D. The third portion 312T1 and the fourth portion 312T2 of the top surface 312T of the dielectric pattern 312 are adjacent to each other and are different portions of the top surface 312T of the dielectric pattern 312. The drain electrode layer 314D is in contact with the top surface 200T of the substrate 200 that is not covered by the interlayer dielectric layer 210, the top surface 210T of the interlayer dielectric layer 210 that is not covered by the dielectric pattern 312 and close to the drain contact feature 224D, and the third portion 312T1 of the top surface 312T of the dielectric pattern 312. In some embodiments, the upper surfaces 314D-IT, 314D-2T, 314D-3T are not coplanar with each other. For example, in the direction 110, the upper surface 314D-1T is located below the upper surface 314D-2T (that is, the upper surface 314D-1T is closer to the top surface 200T of the substrate 200 than the upper surface 314D-2T). In addition, the upper surface 314D-2T is located below the upper surface 314D-3T (that is, the upper surface 314D-2T is closer to the top surface 200T of the substrate 200 than the upper surface 314D-3T).

In some embodiments, the dielectric pattern 212 and dielectric pattern 312 may include the same or similar materials and processes. Furthermore, the dielectric pattern 212 and the dielectric pattern 312 may be formed simultaneously. In some embodiments, the interlayer dielectric layers 210, 216 and dielectric pattern 312 may include different materials. In some embodiments, the dielectric constant of the interlayer dielectric layers 210, 216 is different from the dielectric constant of the dielectric pattern 312. The dielectric constant of the interlayer dielectric layers 210, 216 may be less than the dielectric constant of the dielectric pattern 312. For example, the interlayer dielectric layers 210 and 216 are silicon dioxide (k=3.9), and the dielectric pattern 312 is silicon nitride (k=7.5).

As shown in FIG. 2, the field plate 318F1 is disposed on the interlayer dielectric layer 216 and the dielectric pattern 312. The field plate 318F1 partially overlaps the drain electrode layer 314D on the top surface 312T of the dielectric pattern 312. In addition, the field plate 318F1 extends toward drain contact feature 224D in the direction 100. More specifically, in the direction 110, the field plate 318F1 overlaps the drain electrode layer 314D on the third portion 312T1 of the top surface 312T of the dielectric pattern 312. The field plate 318F1 does not overlap the portion of the drain electrode layer 314D on the top surface 210T of the interlayer dielectric layer 210 that is not covered by the dielectric pattern 312 and close to the drain contact feature 224D. Furthermore, the field plate 318F1 does not overlap the portion of the drain electrode layer 314D located on the barrier layer 206 that is not covered by the interlayer dielectric layer 210. Therefore, the field plate 318F1 is closer to the gate structure 220 than the drain electrode layer 314D. As shown in FIG. 2, the field plate 318F1 may extend from the top surface 210T of the field plate 318F1 that is not covered by the drain electrode layer 314D and the dielectric pattern 312 and close to the gate structure 220 to cover the fourth portion 312T2 of the top surface 312T of electrical pattern 312, and a first portion 314D-3TA of the upper surface 314D-3T of the drain electrode layer 314D. Therefore, a second portion 314D-3TB of the upper surface 314D-3T is exposed from the field plate 318F1. The first portion 314D-3TA and the second portion 314D-3TB of the upper surface 314D-3T of the drain electrode layer 314D are adjacent to each other and are different portions of the upper surface 314D-3T of the drain electrode layer 314D.

In the direction 100, the upper surface 314D-3T of the drain electrode layer 314D has a length L3, and the first portion 314D-3TA of the upper surface 314D-3T has a length L4. In some embodiments, the ratio of length L3 to length L4 is greater than or equal to 2 (i.e., L3/L4≥2). If the ratio of the length L3 to the length L4 is less than 2, the overlapping portion of the field plate 318F1 and the drain electrode layer 314D may be too large and affect the uniformity of the surface electric field.

In some embodiments, the field plate 318F1 is conformally formed on the interlayer dielectric layer 210, the dielectric pattern 312, and drain electrode layer 314D. In the cross-sectional view shown in FIG. 2, the drain electrode layer 314D has a stepped shape. In this embodiment, the step number of the stepped drain electrode layer 314D is 3. Therefore, the field plate 318F1 may have three upper surfaces 318F1-1T, 318F1-2T, 318F1-3T. In addition, the field plate 318F1 may have opposite side surfaces 318F1-S1, 318F1-S2 connected to the upper surfaces 318F1-1T, 318F1-3T respectively. As shown in FIG. 1, the upper surface 318F1-1T of the field plate 318F1 is located directly above the top surface 210T of the interlayer dielectric layer 210 that is not covered by the drain electrode layer 314D and the dielectric pattern 312. The upper surface 318F1-2T of the field plate 318F1 is located directly above the fourth portion 312T2 of the top surface 312T of the dielectric pattern 312 that is not covered by the drain electrode layer 314D. The upper surface 318F1-3T of the field plate 318F1 is located directly above the first portion 314D-3TA of the upper surface 314D-3T of the drain electrode layer 314D. In some embodiments, the upper surfaces 318F1-1T, 318F1-2T, 318F1-3T of the field plate 318F1 are not coplanar with each other. For example, in the direction 110, the upper surface 318F1-1T is located below the upper surface 318F1-2T (that is, the upper surface 318F1-1T is closer to the top surface 200T of the substrate 200 than the upper surface 318F1-2T). In addition, the upper surface 318F1-2T is located below the upper surface 318F1-3T (that is, the upper surface 318F1-2T is closer to the top surface 200T of the substrate 200 than the upper surface 318F1-3T).

As shown in FIG. 2, the side surface 318F1-S1 of the field plate 318F1 close to the gate structure 220 is not located directly above the drain electrode layer 214D and the dielectric pattern 312. In addition, the side surface 318F1-S2 of the field plate 318F1 close to the drain structure 330D is located directly above the drain electrode layer 314D. Therefore, the side surface 318F1-S1 of the field plate 318F1 close to the gate structure 220 is closer to the gate structure 220 than the side surface 314D-S of the drain electrode layer 314D close to the gate structure 220.

The semiconductor device 500B has the advantages of the semiconductor device 500A. Furthermore, in this embodiment, the drain electrode layer 314D is a 3-step stepped drain electrode layer conformally formed on the barrier layer 206, the interlayer dielectric layer 210 and the dielectric pattern 312. The field plate 318F1 is a 3-step stepped field plate conformally formed on the interlayer dielectric layer 216, the dielectric pattern 312 and the drain electrode layer 214D and fabricated using a single-layer field plate process. In addition to the advantages of the field plate 218F1 of the semiconductor device 500A, the field plate 318F1 may have the electric field redistribution ability comparable to the multi-layer field plate structure while saving the fabrication cost of the two-layer field plate structure (such as the fabrication cost of the photomask).

In addition, when the dielectric pattern 312 of the semiconductor device 500B is formed of a high-k dielectric material, such as silicon nitride, and the interlayer dielectric layer 210 is formed of silicon dioxide, the dielectric pattern 312 can withstand high electric fields. Therefore, the electric field distribution on the surface of the semiconductor device 500B can be relatively uniform. For example, the electric field peak at the edge of the subsequently formed field plate (for example, the side surface 218F1-S2 of the field plate 218F1 close to the drain structure 330D) can be reduced. In addition, since the interlayer dielectric layer 210 and the dielectric pattern 312 are formed of different dielectric materials, the interlayer dielectric layer 210 may serve as an etching stop layer for the dielectric pattern 312 during the patterning process (including lithography and etching processes) for forming the dielectric pattern 312. In addition, the thickness of the interlayer dielectric layer 210 can be precisely controlled. Therefore, the figure of merit (FOM) of the semiconductor device 500B (for example, the pinch-off voltage of the semiconductor device 500B) can be further improved.

Embodiments of the disclosure provide a semiconductor device, such as a high electron mobility transistor (HEMT) device. The semiconductor device may include a plurality of the field plates, which can make the electric field distribution on the surface of the semiconductor device relatively uniform. The field plates may include a field plate (e.g. the field plate 218F1) disposed on the drain side of the semiconductor device (close to the drain structure) and overlapping the drain electrode layer, and field plates disposed between the gate structure and the drain structure and overlapping the dielectric pattern (e.g., the field plate 214F and the field plate 218F2).

In some embodiments, the drain electrode layer is a 2-step stepped drain electrode layer. In addition, the field plate overlapping the drain electrode layer is a 2-step stepped field plate that is conformally formed on the drain electrode layer. In addition, the 2-step stepped field plate is electrically floating and fabricated using a single-layer field plate process. Therefore, the 2-step stepped field plate may have the electric field redistribution ability comparable to the multi-layer field plate structure while saving the fabrication cost of a single-layer field plate structure (such as the fabrication cost of the photomask). Therefore, the number of the field plates and the capacitance generated between the gate electrode and the drain region can be reduced. The product of the on-resistance (drain-to-source on resistance, R_{DS-ON}) and the output power capacitance (C_{OSS}) of the semiconductor device is reduced accordingly to improve the figure of merit (FOM) of the semiconductor device.

In some embodiments, a dielectric pattern (e.g., the dielectric pattern 312) may be disposed between the first interlayer dielectric layer (e.g., the interlayer dielectric layer 210) and the drain electrode layer. The dielectric pattern may partially overlap the drain electrode layer in the vertical direction. When the drain electrode layer is a 3-step stepped drain electrode layer, the field plate overlapping the drain electrode layer is a 3-step stepped field plate that is conformally formed on the drain electrode layer and the dielectric pattern. In addition, the 3-step stepped field plate is electrically floating and fabricated using a single-layer field plate process. Therefore, the 3-step stepped field plate may have the electric field redistribution ability comparable to the multi-layer field plate structure while saving the fabrication cost of a two-layer field plate structure (such as the fabrication cost of the photomask). Therefore, the figure of merit (FOM) of the semiconductor device is improved.

In some embodiments, the semiconductor device includes a dielectric pattern (e.g., the dielectric pattern 212) disposed on a portion of the first interlayer dielectric layer (e.g., the interlayer dielectric layer 210) between the gate structure and the drain structure. Therefore, the field plate disposed between the gate structure and the drain structure and overlapping the dielectric pattern is formed as a 2-step stepped source field plate. Therefore, the multi-layer (e.g., two-layer) field plate structure can be fabricated by a single-layer field plate process. The 2-step stepped field plate may have the electric field redistribution ability comparable to the multi-layer field plate structure while saving the fabrication cost of a single-layer field plate structure (such as the fabrication cost of the photomask), and avoid large electric field peaks. Furthermore, the distance between each field plate and the barrier layer can be adjusted to reduce the on-resistance (drain-to-source on resistance, R_{DS-ON}) and the capacitance generated between the gate electrode and the drain region. The breakdown voltage of the high electron mobility transistor (HEMT) device is increased accordingly to improve the figure of merit (FOM) of the semiconductor device.

In some embodiments, the dielectric pattern close to the drain structure or close to the gate structure is in contact with the first interlayer dielectric layer thereunder. In addition, the dielectric pattern and the first interlayer dielectric layer thereunder are formed of dielectric materials with different dielectric constants. For example, the first interlayer dielectric layer may be formed of silicon dioxide, and the dielectric pattern may be formed of a high-k dielectric material, such as silicon nitride. The dielectric pattern having high dielectric constant can make the electric field distribution on the surface of the semiconductor device more uniform. Moreover, during the etching process for forming the dielectric pattern, the first interlayer dielectric layer can serve as an etching stop layer of the etching process. Therefore, the variation of the thickness of the first interlayer dielectric layer cause by the etching process is eliminated. The figure of merit (FOM) of the semiconductor device is improved accordingly.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
a gate structure disposed on the substrate;
a first interlayer dielectric layer disposed on the substrate and partially covering the substrate and the gate structure;
a drain structure disposed on the substrate and located on a first side of the gate structure, wherein the drain structure comprises:
a drain electrode layer disposed on the substrate and extending from the substrate that is not covered by the first interlayer dielectric layer to cover a portion of a first top surface of the first interlayer dielectric layer;
a second interlayer dielectric layer disposed on the first interlayer dielectric layer and covering the drain electrode layer; and
a first field plate disposed on the second interlayer dielectric layer and partially overlapping the drain electrode layer on the first top surface of the first interlayer dielectric layer, wherein the first field plate is electrically floating.

2. The semiconductor device as claimed in claim 1, wherein the drain electrode layer comprises:
a first upper surface located directly above a second top surface of the substrate that is not covered by the first interlayer dielectric layer; and
a second upper surface located directly above the first top surface of the first interlayer dielectric layer, wherein the first upper surface and the second upper surface are not coplanar with each other.

3. The semiconductor device as claimed in claim 2, wherein the first upper surface is located below the second upper surface.

4. The semiconductor device as claimed in claim 2, wherein the first field plate covers a first portion of the second upper surface.

5. The semiconductor device as claimed in claim 4, wherein in a first direction, the second upper surface has a first length, the first portion of the second upper surface has a second length, and the ratio of the first length to the second length is greater than or equal to 2.

6. The semiconductor device as claimed in claim 2, wherein in a cross-sectional view, the drain electrode layer and the first field plate both have a stepped shape.

7. The semiconductor device as claimed in claim 6, wherein the first field plate comprises:
a third upper surface located directly above the first interlayer dielectric layer that is not covered by the drain electrode layer; and
a fourth upper surface located directly above the second upper surface of the drain electrode layer, wherein the third upper surface is located below the fourth upper surface.

8. The semiconductor device as claimed in claim 7, further comprising:
a first dielectric pattern disposed on the first interlayer dielectric layer between the gate structure and the drain structure, wherein the drain electrode layer is in contact with a third portion of a third top surface of the first dielectric pattern.

9. The semiconductor device as claimed in claim 8, wherein in a first direction, the first dielectric pattern is spaced apart from the gate structure by a first distance, the first dielectric pattern is spaced apart from a drain contact feature of the drain structure by a second distance, and the first distance is greater than the second distance.

10. The semiconductor device as claimed in claim 8, wherein the first interlayer dielectric layer and the first dielectric pattern comprise different materials.

11. The semiconductor device as claimed in claim 8, wherein the drain electrode layer further comprises:
a fifth upper surface located directly above the third portion of the third top surface of the first dielectric pattern.

12. The semiconductor device as claimed in claim 11, wherein the fifth upper surface is located above the second upper surface.

13. The semiconductor device as claimed in claim 11, wherein the first field plate further comprises:
a sixth upper surface located directly above a fourth portion of the third top surface of the first dielectric pattern, wherein the third portion and the fourth portion are adjacent to each other and are different portions of the third top surface of the first dielectric pattern, wherein:
the third upper surface is located directly above the first interlayer dielectric layer that is not covered by the first dielectric pattern,
the fourth upper surface is located directly above the third portion of the third top surface of the first dielectric pattern, wherein the third upper surface is located below the sixth upper surface, and the sixth upper surface is located below the fourth upper surface.

14. The semiconductor device as claimed in claim 1, wherein the drain structure further comprises:
a drain contact feature located on the drain electrode layer and passing through the second interlayer dielectric layer; and
a drain metal layer located on the drain contact feature, wherein the drain electrode layer and the drain metal layer extend in a first direction, and the drain contact feature extends in a second direction.

15. The semiconductor device as claimed in claim 14, wherein in the second direction, the first field plate partially overlaps the drain metal layer.

16. The semiconductor device as claimed in claim 14, further comprising:
a source structure disposed on the substrate and located on a second side of the gate structure, wherein the source structure comprises;
a source electrode layer disposed on the substrate, extending in the first direction and partially covering the first top surface of the first interlayer dielectric layer, wherein opposite side surfaces of the first interlayer dielectric layer are respectively covered by the drain electrode layer and the source electrode layer;
a source contact feature located on the source electrode layer and extending through the second interlayer dielectric layer in the second direction; and
a source metal layer located on the source contact feature, wherein the source electrode layer and the source metal layer extend in the first direction, and the source contact feature extends in the second direction.

17. The semiconductor device as claimed in claim 16, further comprising:
a second dielectric pattern disposed on the first interlayer dielectric layer between the gate structure and the drain structure, wherein the first interlayer dielectric layer and the second dielectric pattern comprise different materials;
a second field plate disposed on the substrate and covering the first interlayer dielectric layer between the gate structure and the second dielectric pattern and the second dielectric pattern; and
a third field plate disposed on the second interlayer dielectric layer directly above the second dielectric pattern and partially overlapping the second field plate, wherein in the first direction, the second field plate is closer to the gate structure than the third field plate, and the third field plate is closer to the gate structure than the first field plate.

18. The semiconductor device as claimed in claim 17, wherein the second field plate and the third field plate are electrically connected to the source structure.

19. The semiconductor device as claimed in claim 17, wherein the second field plate comprises:
a seventh upper surface located directly above the first interlayer dielectric layer between the gate structure and the second dielectric pattern; and
an eighth upper surface located directly above a fifth portion of a fourth top surface of the second dielectric pattern, wherein the seventh upper surface is located below the eighth upper surface.

20. The semiconductor device as claimed in claim 19, wherein the third field plate comprises:
a ninth upper surface located directly above the fifth portion of the fourth top surfaces of the second dielectric pattern; and
a tenth upper surface located directly above a sixth portion of the fourth top surface of the second dielectric pattern, wherein the ninth upper surface is located above the tenth upper surface, wherein the fifth portion and the sixth portion are adjacent to each other and are different portions of the fourth top surface of the second dielectric pattern.
